(19) United States
(12) Patent Application Publication
(10) Pub. No.: US 2024/0396505 A1
(43) Pub. Date: Nov. 28, 2024

(54) AMPLIFIER OVERDRIVE PROTECTION WITH VOLTAGE COMPARATOR

(71) Applicant: Texas Instruments Incorporated, Dallas, TX (US)

(72) Inventor: Divya Kaur, Delhi (IN)

(21) Appl. No.: 18/471,540

(22) Filed: Sep. 21, 2023

(30) Foreign Application Priority Data
May 24, 2023 (IN) 202341035928

(51) Int. Cl. H03F 1/52; H03F 3/04; H03G 3/30

(52) U.S. Cl. CPC H03F 1/52; H03F 3/04; H03G 3/30; H03F 2200/426; H03G 2201/103

(57) ABSTRACT

Techniques for providing amplifier overdrive protection. In an example, a circuit configured to determine the difference between the amplifier output voltage and the amplifier power supply voltage, so as to sense an overdrive condition. Responsive to the difference exceeding a threshold, the circuit is configured to limit the amplifier drive capability, which in turn limits the maximum amplifier output current. The circuit may restore the amplifier drive capability, responsive to cessation of the overdrive condition. In some such cases, the circuit may be configured with hysteresis, so as to provide stability when transitioning to and from the reduced drive state. Another example circuit operates in a similar fashion but is configured to determine the difference between the amplifier input voltage and a reference voltage, so as to sense an overdrive condition. In some such cases, the reference voltage may be equal to amplifier power supply voltage divided by amplifier gain.

### CROSS-REFERENCE TO RELATED APPLICATION

This application claims the benefit of and priority to India (IN) Provisional Patent Application No. 202341035928 filed on May 24, 2023, which is incorporated herein by reference in its entirety.

### TECHNICAL FIELD

This description relates to amplifiers, and in particular, to amplifier overdrive protection.

### BACKGROUND

An amplifier is a circuit that applies a gain factor (G) to an input signal (VIN) at the amplifier input, and provides an output signal (VOUT) at the amplifier output having a magnitude of VIN*G. The gain factor G can vary, depending on the application. In some cases, the gain factor G may be less than 1 so as to attenuate the input signal (VOUT<VIN), while in other cases the gain factor G may be greater than 1 so as to amplify the input signal (VOUT>VIN). In still other cases, the gain factor G may be equal to 1 so as to provide a unity gain amplifier (VOUT =VIN). When any such amplifier circuit is overdriven, the amplifier may draw input current that exceeds the normal range of input bias current, which can damage the amplifier or surrounding circuitry. As such, some amplifiers are configured with overdrive protection. A number of non-trivial issues remain with amplifier overdrive protection techniques.

### SUMMARY

In an example, a circuit includes: a power supply terminal for receiving a power supply voltage of an amplifier; an input terminal for receiving an output voltage of the amplifier; an output terminal; and a gain adjust circuit. The gain adjust circuit is configured to adjust gain of the amplifier, responsive to a difference between the amplifier output voltage and the amplifier power supply voltage exceeding a threshold voltage, by providing a gain adjust signal at the output terminal.

In another example, a circuit includes: a power supply terminal for receiving a power supply voltage of an amplifier; an input terminal for receiving an output voltage of the amplifier; an output terminal; a comparator circuit; and a clamp circuit. The comparator circuit has first and second comparator inputs and a comparator output. The first comparator input is coupled to the power supply terminal, and the second comparator input is coupled to the input terminal. The clamp circuit has first and second clamp inputs and a clamp output. The first clamp input is coupled to the power supply terminal, the second clamp input is coupled to the comparator output, and the clamp output is coupled to the output terminal.

In another example, a circuit includes: a power supply terminal for receiving a power supply voltage of an amplifier; an input terminal for receiving an input voltage of the amplifier; an output terminal; and a gain adjust circuit. The gain adjust circuit is configured to adjust gain of the amplifier, responsive to the amplifier input voltage exceeding a reference voltage, by providing a gain adjust signal at the output terminal, the reference voltage being the power supply voltage divided by a gain of the amplifier.

In another example, a method for providing overdrive protection of an amplifier includes determining a difference of an amplifier output voltage and an amplifier power supply voltage. Responsive to the difference exceeding a threshold, the method continues with limiting drive capability of the amplifier thus limiting maximum current at an output of the amplifier. Responsive to the difference not exceeding a threshold, the method continues with restoring the drive capability of the amplifier.

In another example, a method for providing overdrive protection of an amplifier includes comparing an amplifier input voltage to a reference voltage, the reference voltage equal to an amplifier power supply voltage divided by a gain of the amplifier. Responsive to the amplifier input voltage being greater than the reference voltage, the method continues with limiting drive capability of the amplifier thus limiting maximum current at an output of the amplifier. Responsive to the amplifier input voltage not being greater than the reference voltage, the method continues with restoring the drive capability of the amplifier.

### BRIEF DESCRIPTION OF THE DRAWINGS

FIG. 1 illustrates a block diagram of an amplifier system configured with overdrive protection, in an example.

FIG. 2 illustrates a schematic diagram of an amplifier system configured with overdrive protection, in an example.

FIGS. 3A and 3B each illustrates a schematic diagram of an amplifier system configured with overdrive protection, in another example.

FIG. 4 illustrates a schematic diagram of an amplifier system configured with overdrive protection, in another example.

FIG. 5 illustrates a method for providing overdrive protection in an amplifier system, in an example.

FIG. 6 illustrates a method for providing overdrive protection in an amplifier system, in another example.

FIG. 7 illustrates a schematic diagram of a power system configured with amplifier overdrive protection, in an example.

FIG. 8 illustrates a schematic diagram of a power system configured with amplifier overdrive protection, in another example.

FIG. 9 illustrates a schematic diagram of a multiplexer circuit that can be used in the power systems of FIGS. 7 and 8, in some examples.

### DETAILED DESCRIPTION

Techniques are described herein for providing overdrive protection for an amplifier circuit. The amplifier circuit, which may also be called a buffer circuit, can have any number of configurations, and may have any gain factor. The techniques may be implemented, for example, with a voltage-based current clamp that effectively alters the amplifier's loop gain responsive to the amplifier entering its dropout region (amplifier saturation or overdrive) so as to limit the amplifier output current. Advantageously, the techniques can be implemented without loading the amplifier input, and avoid or otherwise reduce leakage current. In an example, the voltage-based current clamp can be implemented in a circuit that is configured to determine a difference between the amplifier output voltage and the amplifier power supply voltage, so as to sense an overdrive condition. Responsive to the difference exceeding a threshold, the circuit is further configured to limit the drive capability of the amplifier, which in turn limits the maximum current at the amplifier output. The circuit may be further configured to restore the amplifier drive capability, responsive to cessation of the overdrive condition. In some such cases, the circuit may be configured with hysteresis, so as to provide stability when transitioning to and from the reduced drive state. Modulating the amplifier drive capability (gain) allows for relatively fast recovery when the amplifier input voltage comes back into an acceptable range of operation. Another example circuit operates in a similar manner, except that the circuit is configured to determine a difference between the amplifier input voltage and a reference voltage, so as to sense an overdrive condition. The reference voltage may be, for example, equal to the amplifier power supply voltage divided by the amplifier gain.

### General Overview

As described above, a number of non-trivial issues remain with amplifier overdrive protection techniques. In more detail, if an expected amplifier output is higher than the amplifier power supply voltage, the amplifier can saturate to a high current state (sometimes referred to as amplifier overdrive, or amplifier dropout). In such a case, pre-driver and output driver circuitry of the amplifier circuit can sink high current, which in turn may damage the circuitry. To help avoid this condition, a conventional voltage clamp including a current comparator can be coupled to the amplifier input. Such a clamp is configured to clamp the voltage at the amplifier input by drawing current from the input, and may also experience some degree of leakage current, both of which causes a loading condition at the otherwise high impedance amplifier input. Such loading or leakage may raise the quiescent current of the overall system, which is particularly undesirable for battery-based systems, where leakage will more quickly deplete the given battery's charge or otherwise shorten battery life. Also, leakage can decrease the accuracy of the system, by causing an incorrect (reduced) voltage at the amplifier input. For example, 5 nanoamps of leakage through a 10 megaohm input resistance generates a 50 millivolt voltage drop. For an amplifier having a 750 millivolt output, such a relatively small amount of leakage represents a 7% inaccuracy, which is relatively high compared to some specifications (e.g., such as those that require inaccuracy be less than 1% or 2%). Also, oscillations may occur at the amplifier input as a result of the clamp engaging (low-state of oscillation) and disengaging (high-state of oscillation). Such oscillations may manifest at the amplifier output and interfere with the performance of the overall system using the amplifier.

Accordingly, techniques are described herein for providing amplifier overdrive protection. The techniques can be implemented, for example, by using a clamp configured to perform voltage comparison instead of current comparison. The clamp can be used to monitor the amplifier output voltage in some cases, or the amplifier input voltage in some other cases. Unlike clamping techniques that involve a current comparison at the amplifier input, the techniques described herein can be implemented with no or otherwise reduced loading at the amplifier input, and may provide faster recovery responsive to cessation of a given amplifier dropout or overdrive condition.

### Circuit Architecture

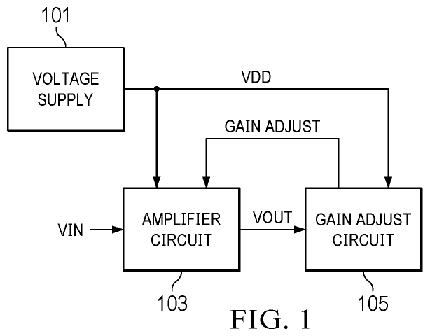

FIG. 1 illustrates a block diagram of an amplifier system configured with overdrive protection, in an example. As shown, the system includes a voltage supply 101, an amplifier circuit 103, and a gain adjust circuit 105. The voltage supply 101 is configured to provide a power supply voltage VDD, which is used for the positive supply rail of amplifier circuit 103. The amplifier circuit 103 receives an input voltage VIN and is configured to provide an output voltage VOUT that is equal to VIN times a gain G of the amplifier circuit 103. The gain adjust circuit 105 generates a gain adjust signal at its output, based on a comparison of the VOUT and VDD voltages. The gain adjust signal is used to tune gain G of the amplifier circuit 103, so as to limit amplifier output current during a dropout condition.

The voltage supply 101 can be implemented with any direct current (DC) power supply or voltage regulator configuration, such as a passive regulator (e.g., series regulator or shunt regulator) or an active regulator (e.g., linear regulator, switching regulator, or silicon controlled rectifier (SCR)), or some combination of these. The value of VDD can vary from one example to the next, but in some cases is in the range of 3 volts to 20 volts (e.g., about 5 volts). More generally, voltage supply 101 and VDD can be any power supply and DC voltage, respectively, suitable for a given application.

The amplifier circuit 103 can be implemented with any amplifier configuration, such as a non-inverting amplifier having a gain G of greater than 1, an inverting amplifier having a gain of less than 1, an inverting amplifier having a gain of greater than 1, or an inverting amplifier having a gain equal to 1. The amplifier circuit may also be a buffer circuit, wherein the buffer circuit output changes responsive to changes on the buffer circuit input. More generally, the amplifier circuit 103 can be any circuit suitable for a given application and that is both (a) susceptible to a dropout or saturation based high current condition caused by application of an input voltage VIN that effectively calls for an output voltage VOUT that is greater than the supply rail voltage of VDD, and (b) has a node to which a voltage-based current clamp can be applied to avoid or otherwise inhibit such a high current condition.

As further shown in the example of FIG. 1, the gain adjust circuit 105 includes a power supply terminal for receiving the power supply voltage VDD that is also received by the amplifier circuit 103, and an input terminal for receiving an output voltage VOUT of the amplifier circuit 103. The gain adjust circuit 105 further includes an output terminal at which the gain adjust signal is provided. As described above, the gain adjust circuit 105 is configured to generate the gain adjust signal based on a difference between the amplifier output voltage VOUT and the amplifier power supply voltage VDD exceeding a threshold voltage. The threshold voltage can be, for example, correlated to or otherwise associated with a dropout voltage specification of the amplifier circuit 103. More generally, the threshold voltage can be any threshold that can be used to indicate the amplifier circuit is about to enter a saturation or dropout mode, because the output voltage being called for exceeds the voltage rail VDD of the amplifier circuit 103.

The gain adjust signal generated by gain adjust circuit 105 in turn can be used to cause adjustment of gain G of amplifier circuit 103. In some examples, for instance, the gain adjust circuit 105 is configured to adjust gain G of the amplifier circuit 103 from a first gain state (normal mode) to a second gain state (current limit mode) responsive to the difference between VOUT and VDD exceeding the threshold voltage, and to restore gain G of the amplifier circuit 103 to the first gain state responsive to the difference between VOUT and VDD no longer exceeding the threshold voltage. In some examples, for instance, gain adjust circuit 105 can accomplish this by setting the gain adjust signal to a logic HIGH responsive to the difference between VOUT and VDD exceeding the threshold voltage, which in turn causes gain G of the amplifier circuit 103 to transition from the first gain state to the second gain state. In a similar fashion, gain adjust circuit 105 can set the gain adjust signal to a logic LOW responsive to the difference between VOUT and VDD no longer exceeding the threshold voltage, which in turn causes gain G of amplifier circuit 103 to transition from the second gain state to the first gain state. A dynamic gain adjustment is thus achieved. The value or state (e.g., HIGH versus LOW, or asserted versus de-asserted) of the gain adjust signal can be used to cause or otherwise set a corresponding gain state of amplifier circuit 103.

Each of voltage supply 101, amplifier circuit 103, and gain adjust circuit 105 may be implemented as a separate circuit as shown, such as separate integrated circuits (ICs) or printed circuit boards (PCBs), although in other embodiments the degree of integration may vary. For instance, in another example, each of voltage supply 101, amplifier circuit 103, and gain adjust circuit 105 may be implemented in a single integrated circuit or on a single PCB. In another example, the gain adjust circuit 105 is integrated with the amplifier circuit 103. More generally, any degree of integration may be used to provide an amplifier system such as shown in FIG. 1, whether at an integrated circuit level, or a PCB level, or at a discrete component level, or some combination thereof.

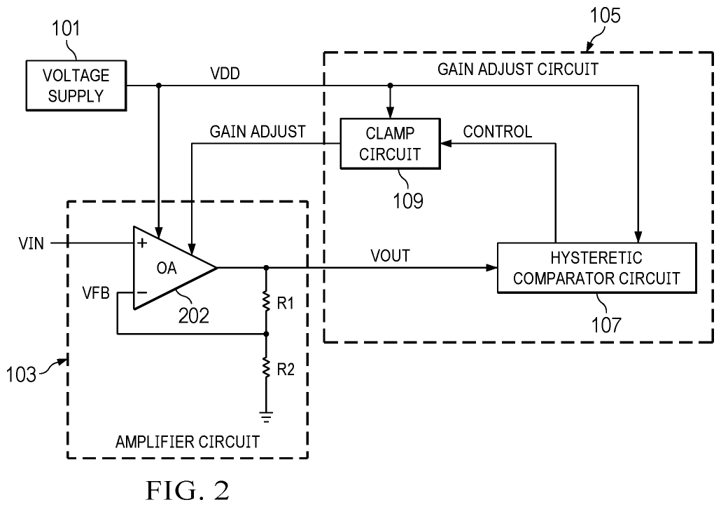

FIG. 2 illustrates a schematic diagram of an amplifier system configured with overdrive protection, in an example. As shown, this example is similar to that shown in FIG. 1, except that further example details of amplifier circuit 103 and gain adjust circuit 105 are provided. The above relevant description equally applies here. Other examples may be configured differently. In this example, amplifier circuit 103 includes an operational amplifier (OA) 202 and resistors R1 and R2 arranged in a non-inverting amplifier configuration, and gain adjust circuit 105 includes a hysteretic comparator circuit 107 and a clamp circuit 109.

The amplifier circuit 103 receives VIN at its non-inverting input, and a feedback signal VFB at its inverting input, wherein VFB equals: [VOUT(R2)]/[R1+R2]. The gain G of the amplifier circuit 103 is this example is equal to: VOUT/VIN, which is equal to 1+ (R1/R2). Such a configuration may be beneficial, as it allows VIN to remain unloaded, because of the very high input impedance at the non-inverting input. However, if loading of the input is less of a concern for the given application, then another example includes the case where the amplifier circuit 103 is configured as an inverting amplifier, which receives VIN at its inverting input and a reference signal (e.g., ground) at its non-inverting input. In such a configuration, resistor R1 would be coupled between the VIN terminal and the inverting input of amplifier circuit 103 (to provide an input resistance), and resistor R2 would be coupled between the inverting input and the output of amplifier circuit 103 (to provide a feedback resistance). In such a case, the gain G is equal to: VOUT/VIN, which is equal to R2/R1.

With further reference to the example of FIG. 2, the comparator circuit 107 has first and second comparator inputs and a comparator output, with the first comparator input being coupled to the VDD terminal, and the second comparator input being coupled to the VOUT terminal. The comparator circuit 107 is configured to compare VOUT and VDD, and to generate a control signal indicative of the difference exceeding the threshold voltage. For instance, in one example case, the comparator circuit 107 is configured to generate a control signal having a HIGH state (engage clamp) responsive to VOUT being greater than VDD less a threshold voltage, and to generate a control signal having a LOW state (disengage clamp) responsive to VOUT being less than or equal to VDD less the threshold voltage. The threshold voltage can be small relative to VDD, such as the example case where VDD is equal to 5 volts and the threshold voltage is in the range of 0.01 volts to 0.9 volts (e.g., 0.1 volts to 0.3 volts). In another example, the threshold voltage can be some percentage of VDD, such as 10% or less (e.g., 0.01% to 5% less than VDD). In some example cases, the threshold signal is or otherwise corresponds to a dropout specification of amplifier circuit 103. Such a dropout specification may be designated, for instance, in the datasheet of the amplifier circuit 103, or is otherwise determinable based on the given application (e.g., amplifier configuration and value of VDD). More generally, the threshold voltage can be set to any value that will allow comparator circuit 107 to reliably and accurately signal an overdrive or dropout condition.

In the example shown, the comparator circuit 107 is a hysteretic comparator circuit, which may be helpful to improve stability of the clamping function, by using different thresholds for engaging and disengaging the clamp. Such a configuration effectively reduces chatter (rapid sequences of clamp engagement and disengagement) that might occur about a single threshold. In one such hysteretic example, a first threshold of comparator circuit 107 can be used for indicating the onset of a dropout condition, and a second threshold of comparator circuit 107 can be used for indicating the cessation of the dropout condition. For instance, the comparator circuit 107 may be configured to set the control signal to a HIGH state (engage clamp) responsive to VOUT being greater than VTH-HI, and to set the control signal to a LOW state (disengage clamp) responsive to VOUT being less than VTH-LO. In one such example, VTH-HI is in the range of VDD less X volts (e.g., X equals 0.1 to 0.25 volts), and VTH-LO is in the range of VDD less Y volts (e.g., Y equals 0.4 to 0.5 volts). More generally, the upper and lower thresholds of comparator circuit 107 can be set as needed for a given application. Other examples need not include hysteresis, in which comparator circuit 107 has a single threshold to trigger entry and departure from the clamping state.

The clamp circuit 109 of this example has first and second clamp inputs and a clamp output, with the first clamp input being coupled to VDD, the second clamp input being coupled to the comparator 107 output (so as to receive the control signal), and the clamp output being coupled to the output terminal of circuit 105. The clamp circuit 109 is configured to provide the gain adjust signal at its output, so as to adjust the gain G of the amplifier circuit 103. The clamp circuit engages (or disengages), responsive to the control signal generated by the comparator circuit 107. In an example, the gain adjust signal generated by the clamp circuit 109 comprises a clamp voltage, and the clamp circuit 109 adjusts the gain of the amplifier circuit 103 by clamping a drive voltage of the amplifier 103 to the clamp voltage. The clamp voltage can vary from one example to the next, but in some cases is equal to the power supply voltage VDD less a relatively small voltage, such as the threshold of a transistor (e.g., source-to-gate voltage of an enhancement field effect transistor) or the forward bias voltage drop of a diode. More generally, the clamp voltage can be any voltage the effectively limits the amplifier output current (drive current) to a desired level when amplifier circuit 103 is in the dropout region.

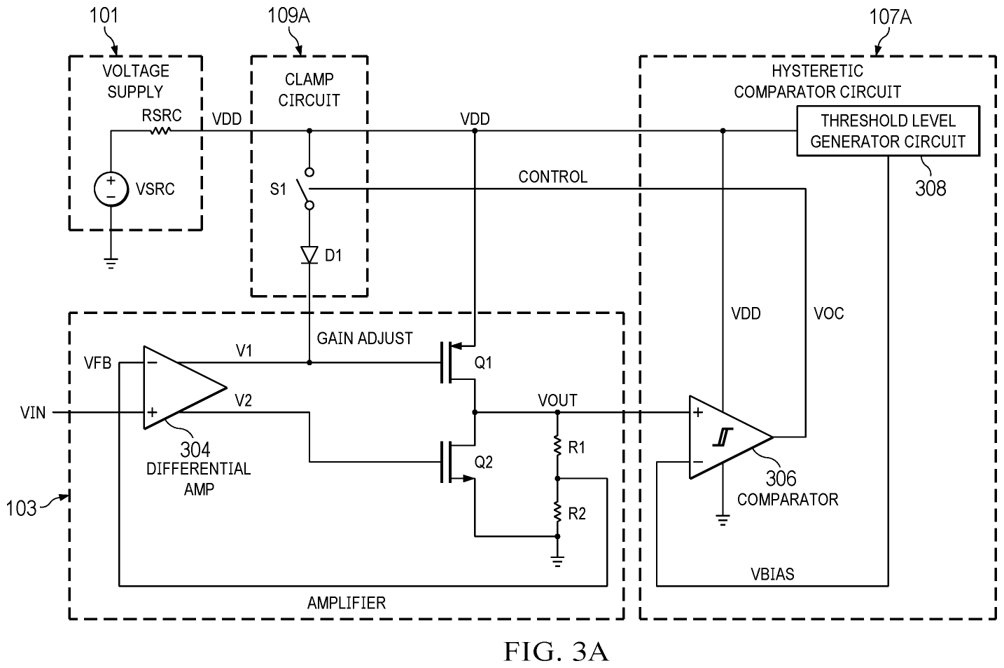

FIG. 3A illustrates a schematic diagram of an amplifier system configured with overdrive protection, in another example. As shown, this example is similar to that shown in FIG. 2, except that further example details of the voltage supply circuit 102, amplifier circuit 103, comparator circuit 107, and clamp circuit 109 are provided. The above relevant description equally applies here. Other examples may be configured differently. In this example, amplifier circuit 103 includes a differential amplifier and transistors Q1 and Q2 arranged in a non-inverting amplifier configuration, which may be one example of how OA 202 is implemented. As further shown in FIG. 3A, circuit 107A includes hysteretic comparator 306 and threshold level generator circuit 308, and clamp circuit 109A includes switch S1 and diode D1. Voltage supply 101 includes a voltage source VSRC and an output resistance RSRC. Ideally, RSRC is zero but may not be achievable in all applications. Transistors Q1 and Q2 of this example are a p-channel field effect transistor (PFET) and an n-channel field effect transistor (NFET), respectively. Other examples may be configured differently and use other transistor technologies, but still provide similar functionality.

The comparator 306 of circuit 107 receives VOUT at its non-inverting input and VBIAS at its inverting input, and provides VOC at its output. VOC is the control signal used to engage or disengage the clamp circuit 109A, and VBIAS is a reference voltage generated by the threshold level generator circuit 308. VBIAS may be slightly less than VDD, such as 10% less than VDD, or 5% less than VDD, or 2% less than VDD. The threshold level generator circuit 308 may be implemented with any number of circuits, such as a diode, a diode-connected transistor, a resistive divider, or some other voltage reference circuit that can take in VDD as input and generate VBIAS at its output. Comparator 306 may be any chip, chip set, or circuit that can provide a hysteretic comparator function based on VOUT and VBIAS at its inputs, so as to generate the VOC control signal. Other examples may include a non-hysteretic comparator circuit 306, which may work as well.

As further shown in this example, the switch S1 of clamp circuit 109A is controlled by the control signal provided by circuit 107A. The switch S1 and diode D1 are serially coupled between the VDD terminal and a drive voltage terminal of the differential amplifier 304. In this example, switch S1 is coupled between the VDD terminal and the diode D1, but in another example may be coupled between the diode D1 and the drive voltage terminal of amplifier 304 (the order of these serially coupled components is reversible). In operation, if a dropout condition is sensed by comparator 306, then an active state of the control signal is asserted thereby causing switch S1 to close, which in turn clamps voltage V1 of amplifier 304 to VDD less the forward bias voltage drop of D1 (e.g., 0.3 volts or 0.7 volts, or any other threshold voltage suitable for a given application). Without such overdrive protection, then an undesirable high current condition may occur. In more detail, if the value of VIN rises to level such that VOUT (ideal) would be greater than VDD, then V1 will drop to 0 volts thereby causing significant current flow from VDD to transistor Q1. If RSRC is relatively high, then VDD can collapse and/or amplifier circuit 103 can be damaged. The clamp circuit 109A of the gain adjust circuit 105 can thus be used to clamp V1 to a non-zero or otherwise overdrive-inhibiting potential, thereby limiting the amount of current that can be output by amplifier circuit 103, at the VOUT terminal. The voltage V2 is complementary (differential) to V1.

FIG. 3B illustrates a schematic diagram of an amplifier system configured with overdrive protection, in another example. As shown, this example is similar to that shown in FIG. 3A, except that different configurations are shown for the comparator and clamp circuits, at 107B and 109B, respectively. The above relevant description equally applies here. Other examples may be configured differently. In this example, circuit 107B includes current sources I1 through I3 along with transistors Q3 through Q7 and resistor R3, and clamp circuit 109A includes switch S1 and transistor Q8.

Similar to the comparator circuit 107A and the clamp circuit 109A of FIG. 3A described above, the comparator circuit 107B and the clamp circuit 109B collectively operate to: decrease the gain G of the amplifier circuit 103 from a first gain to a second gain, responsive to the difference between VOUT and VDD exceeding a first threshold voltage (clamp enable threshold), by asserting the gain adjust signal (in this example, at the output of clamp circuit 109B); and restore the gain G of the amplifier circuit 103 to the first gain, responsive to the difference between VOUT and VDD no longer exceeding a second threshold voltage (clamp disable threshold), by de-asserting the gain adjust signal. The first and second threshold voltages allow for hysteresis. More generally, the switch S1 of the clamp circuit 109B is enabled responsive to VOUT increasing to the clamp enable threshold voltage level (VTH-HI), and the switch S1 of the clamp circuit 109B is disabled responsive to VOUT decreasing to the clamp disable threshold voltage level (VTH-LO).

With further reference to the example of FIG. 3B, transistor Q3 has a diode-connected configuration, with its first current terminal (e.g., source) coupled to the VDD power supply terminal or rail, and its second current terminal (e.g., drain) coupled to its control terminal (e.g., gate) as well as to the ground terminal via resistor R3 and current source I1. Resistor R3 is coupled between the second current terminal of transistor Q3 and current source I1, and provides a voltage drop that determines the threshold voltage for triggering the clamp circuit 109B. The VBIAS node is between resistor R3 and current source I1, and current source I1 is coupled between the VBIAS node and the ground terminal. Transistor Q4 has its first current terminal (e.g., source) coupled to the VOUT terminal of amplifier circuit 103, its second current terminal (e.g., drain) coupled to the comparator output terminal (VOC node, at which the control signal is provided), and its control terminal (e.g., gate) coupled the VBIAS node. The current source I2 is coupled between the VOC node and the ground terminal. Transistor Q5 has its first current terminal (e.g., drain) coupled to the VDD terminal via current source I3, its second current terminal (e.g., source) coupled to the ground terminal, and its control terminal coupled to the VOC node. The VOCZ node between the first current terminal of Q5 and current source I3 provides a signal that is complementary to the signal on the VOC node.

Transistor Q6 is sized to be N times larger than transistor Q4 (with N being an integer greater than or equal to 2) so as to allow for a hysteretic effect, by providing an offset voltage between a first threshold for enabling the clamp circuit 109 and a second threshold for disabling the clamp circuit 109B. This offset is afforded by the lower on-resistance (RDS_on) of transistor Q6, relative to the on-resistance (RDS_on) of Q4. Transistor Q6 has its first current terminal (e.g., source) coupled to the VOUT terminal, and its control terminal coupled to the control terminal of transistor Q4. Transistor Q7 effectively acts as a switch and has its first current terminal (e.g., source) coupled to the second current terminal (e.g., drain) of transistor Q6, its second current terminal coupled to VOC node, and its control terminal coupled to the first current terminal of transistor Q5.

In operation, the voltage drop across resistor R3 is equal to I1 (R3), or VR3, and the voltage at the VBIAS node is equal to VDD less the threshold voltage of Q3 and less VR3, such that:

$$VBIAS = VDD - V S {G}_{Q 3} - ( I 1 ( R 3 ) ) . \qquad Equation 1$$

In this example, Q3 is a PFET and its threshold voltage is its source-to-gate voltage (VSG). Also, comparator circuit 107B sets the voltage at the VOC node to a logic HIGH, responsive to value of VOUT less the threshold voltage of Q4 being greater than the voltage at the VBIAS node, such that:

$$VOC = HIGH , responsive to ( VOUT - V S {G}_{Q 4} ) > VBIAS . \qquad Equation 2$$

In this example, Q4 is a PFET and its threshold voltage is its VSG. Substituting in Equation 1 for VBIAS into Equation 2 provides:

$$VOC = HIGH , responsive to ( VOUT - V S {G}_{Q 4} ) > ( VDD - V S {G}_{Q 3} - ( I 1 ( R 3 ) ) ) . \qquad Equation 3$$

Assuming that Q3 and Q4 are well-matched transistors and thus VSGQ₃ is equal to VSGQ₄, then Equation 3 reduces to:

$$VOC = HIGH , responsive to VOUT > ( VDD - ( I 1 ( R 3 ) ) . \qquad Equation 4$$

Thus, the VOC node (and thus, the control signal) can be set HIGH by comparator circuit 107B so as to assert or otherwise engage the clamp circuit 109B, responsive to VOUT>(VDD−(I1(R3)). Conversely, the VOC node (and thus, the control signal) can be set LOW by comparator circuit 107B so as to de-assert or otherwise disengage the clamp circuit 109B, responsive to VOUT≤(VDD−(I1(R3)), or in the case of a hysteretic comparison, VOUT≤(VDD−(I1(R3)−VHYS). The hysteretic threshold voltage VHYS can be, for instance, the offset voltage afforded by the lower RDS_on of Q6, relative to the RDS_on of Q4, as described above.

The clamp circuit 109B of this example is similar to the clamp circuit 109A, except that it is implemented with a diode-connected transistor Q8 rather than diode D1. The circuit functions in a similar manner. For instance, if a dropout condition is sensed by comparator circuit 107B, then an active state (e.g., logic HIGH) of the control signal is asserted thereby causing switch S1 to close, which in turn clamps voltage V1 of amplifier 304 to VDD less the forward bias voltage drop of Q8. The clamp circuit 109B can thus be used to clamp V1 to a non-zero potential (any potential that limits the amount of current that can be output by amplifier circuit 103 at the VOUT terminal). If the comparator circuit 107B senses the dropout condition has ceased, then the control signal is de-asserted to a LOW state, thereby causing switch S1 to open, which in turn removes the clamp voltage from the V1 node of amplifier 304.

Transistors Q3, Q4, Q6, Q7, Q8 of this example are PMOS FETs, and transistor Q5 is an NMOS FET. Other examples may be configured differently and use other transistor technologies, but still provide similar functionality.

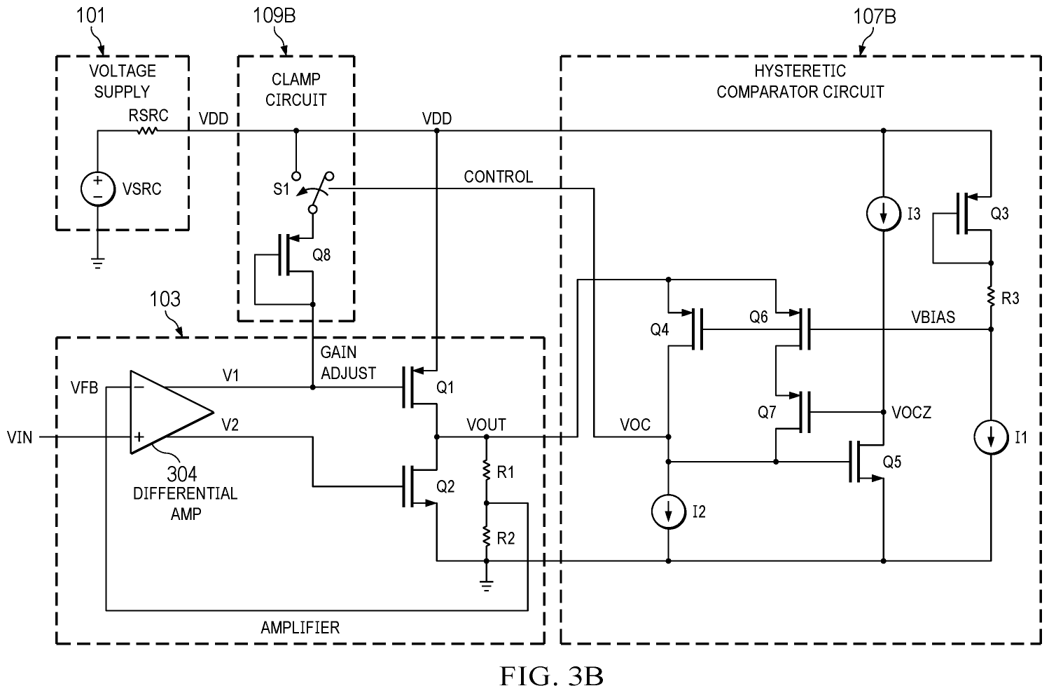

FIG. 4 illustrates a schematic diagram of an amplifier system configured with overdrive protection, in another example. As shown, this example system includes a voltage supply circuit 101 and an amplifier circuit 103 that can be similar to those described above, and that above relevant description is equally applicable here. The system further includes gain adjust circuit 410, which includes a power supply terminal for receiving a power supply voltage of an amplifier (designated as VDD herein), an input terminal for receiving an input voltage of the amplifier (designated as VIN herein), and an output terminal for providing a gain adjust signal. In operation, the gain adjust circuit 410 is configured to adjust gain G of the amplifier circuit 103, responsive to the amplifier input voltage VIN exceeding a reference voltage VREF, by providing a gain adjust signal at the output terminal. The reference voltage VREF can vary from one example to the next, but in some cases is equal to the power supply voltage VDD divided by the gain G of the amplifier. Unlike gain adjust circuit 105 which senses VOUT, gain adjust circuit 410 senses VIN but still does not load the input of amplifier circuit 103, because of the very high input impedance of the gain adjust circuit 410.

In more detail, gain adjust circuit 410 includes a comparator circuit implemented with operational amplifier (OA) 412 configured to compare VIN (received on non-inverting input) and reference voltage VREF (received on inverting input), and to generate a control signal that is either indicative of VIN exceeding VREF (clamp enable) or VIN not exceeding VREF (clamp disable). The gain adjust circuit 410 also includes a clamp circuit 109 configured to adjust gain G of the amplifier circuit 103, responsive to the control signal, as explained above with reference to FIGS. 2 and 3A-B. Unlike clamps that include a current comparison circuit, the operational amplifier 412 doesn't load the input of operational amplifier 202, due to the very high input impedance (e.g., many megaohms, or higher, such as gate impedance of FET) which inhibits any input current at the non-inverting terminal. The operational amplifier 412 is configured to set the control signal to a first state (clamp enable) so as to adjust gain G of amplifier circuit 103 from a first gain to a second gain responsive to VIN exceeding VREF, and to set the control signal to a second state (clamp disable) so as to restore G of amplifier circuit 103 to the first gain responsive to VIN no longer exceeding VREF.

The clamp circuit 109 can be implemented as described above, so as to adjust gain G by clamping a drive voltage of amplifier circuit 103 to a clamp voltage. In some such cases, the clamp voltage may be, for instance, the power supply voltage VDD less a device threshold voltage or some other relatively small voltage drop. The clamp circuit may include, for instance, a switch and a diode or diode-connected transistor coupled in series between the VDD terminal and a drive voltage node of the amplifier. The switch is responsive to the control signal generated by the amplifier 412, such that the clamp circuit engages in response to the control signal being asserted or otherwise set to an active state, and the clamp circuit disengages in response to the control signal being de-asserted or otherwise set to an inactive state.

### Methodology

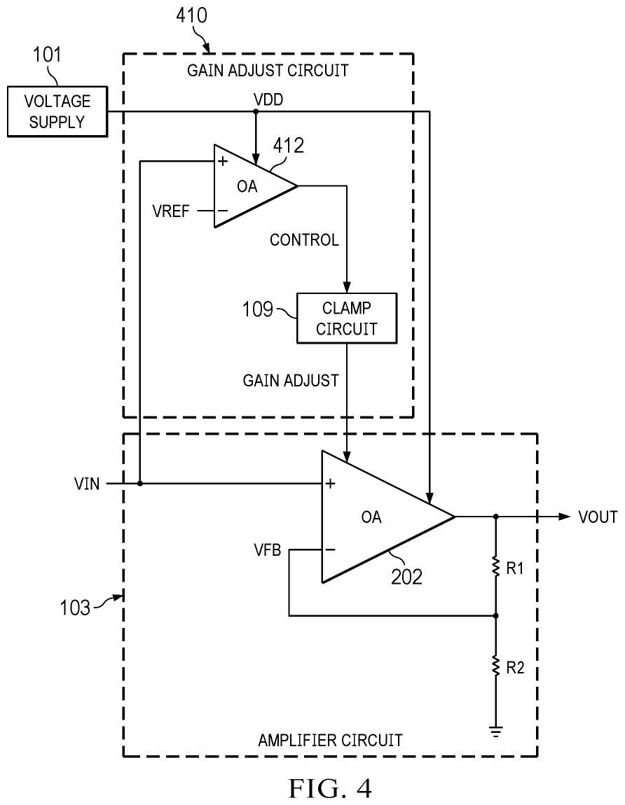

FIG. 5 illustrates a method for providing overdrive protection in an amplifier system, in an example. The methodology can be carried out, for example, by any of the systems shown in FIGS. 1-3B, although other systems capable of limiting an amplifier's drive capability based on a comparison of that amplifier's output voltage to its supply rail voltage can be used. In an example, the methodology uses a clamp configured to perform a voltage comparison rather than a current comparison, so as to avoid loading at the amplifier input.

The method includes determining, at 551, the difference of the amplifier output voltage (e.g., VOUT) and the amplifier power supply voltage (e.g., VDD). This voltage comparison can be carried out, for instance, by a comparator circuit, such as 107, 107A or 107B. In some such cases, the comparator circuit may be a hysteretic comparator, so as to provide a first comparison threshold (clamp engage threshold) and a second comparison threshold (clamp disengage threshold).

Responsive to the difference exceeding a threshold, the method continues, at 553, with limiting the drive capability of the amplifier, which in turn limits the maximum current at the amplifier output. In the example of FIG. 3B, for instance, the threshold is set by the voltage drop across R3, as indicated in Equation 4 above. The voltage drop can be zero or otherwise relatively small, ranging from about 0 volts to some percentage of the power supply voltage (e.g., 10%, 5%, 2%, or 1%). Thus, if the amplifier output voltage reaches or otherwise comes to close to the power supply voltage, then the amplifier's drive capability is limited. In some examples, this limiting of amplifier drive capability is achieved by applying a voltage-based current clamp to a drive node of the amplifier. Voltage-clamping on other amplifier nodes that brings about a similar effect can also be used.

Responsive to the difference not exceeding a threshold, the method continues, at 555, with restoring the drive capability of the amplifier. This can be accomplished, for instance, by disengaging the voltage-based current clamp that is engaged at 553, such as by opening switch S1 as described above. Thus, a relatively real-time modulation of the amplifier's drive capability may be achieved.

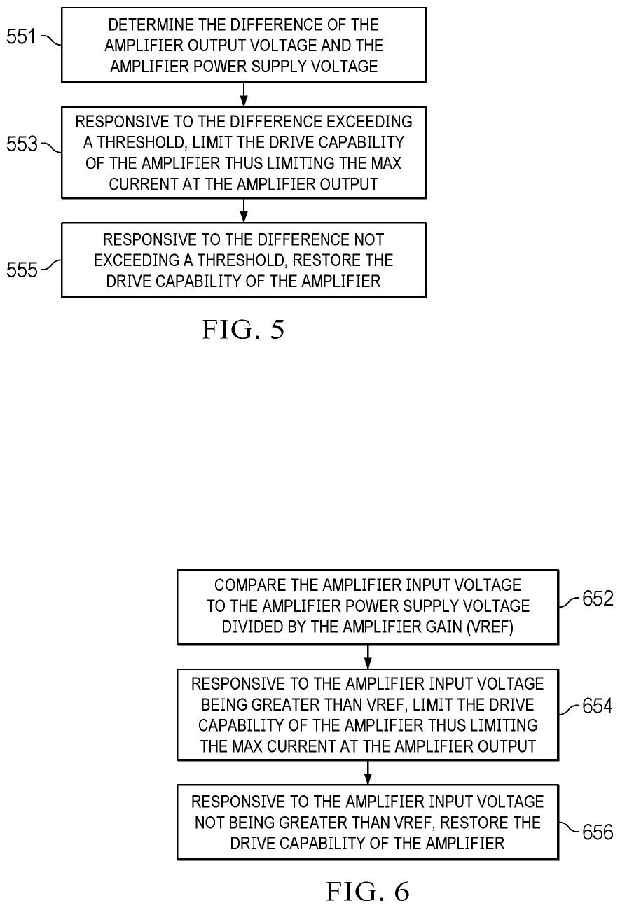

FIG. 6 illustrates a method for providing overdrive protection in an amplifier system, in another example. The methodology can be carried out, for example, by the system shown in FIG. 4, although other systems capable of limiting an amplifier's drive capability based on a comparison of that amplifier's input voltage against a reference voltage can be used. In an example, the methodology uses a clamp configured to perform a voltage comparison rather than a current comparison, so as to avoid loading at the amplifier input.

The method includes, at 652, comparing the amplifier input voltage (e.g., VIN) to a reference voltage VREF. In some such examples, VREF is equal to the amplifier power supply voltage (e.g., VDD) divided by the amplifier gain (G). Such a reference voltage allows for identification of a maximum input voltage VIN that can be tolerated without entering an overdrive or dropout condition, because VIN (G)=VOUT, and thus VIN=VOUT/G. With the acknowledgement that VOUT cannot exceed VDD if overdrive is to be avoided, then substituting in VDD for VOUT yields VIN=VDD/G, which is the maximum input voltage that can be tolerated without triggering an overdrive condition.

Responsive to the amplifier input voltage being greater than VREF, the method continues, at 654, with limiting the drive capability of the amplifier thus limiting the max current at the amplifier output, which in turn limits the maximum current at the amplifier output. In some examples, this limiting of amplifier drive capability is achieved by applying a voltage-based current clamp to a drive node of the amplifier, similar to that described above. The above relevant description is equally applicable here.

Responsive to the amplifier input voltage not being greater than VREF, the method continues, at 656, with restoring the drive capability of the amplifier. This can be accomplished, for instance, by disengaging the voltage-based current clamp that is engaged at 654, such as by opening switch S1 as described above. Thus, a relatively real-time modulation of the amplifier's drive capability may be achieved.

### Power System

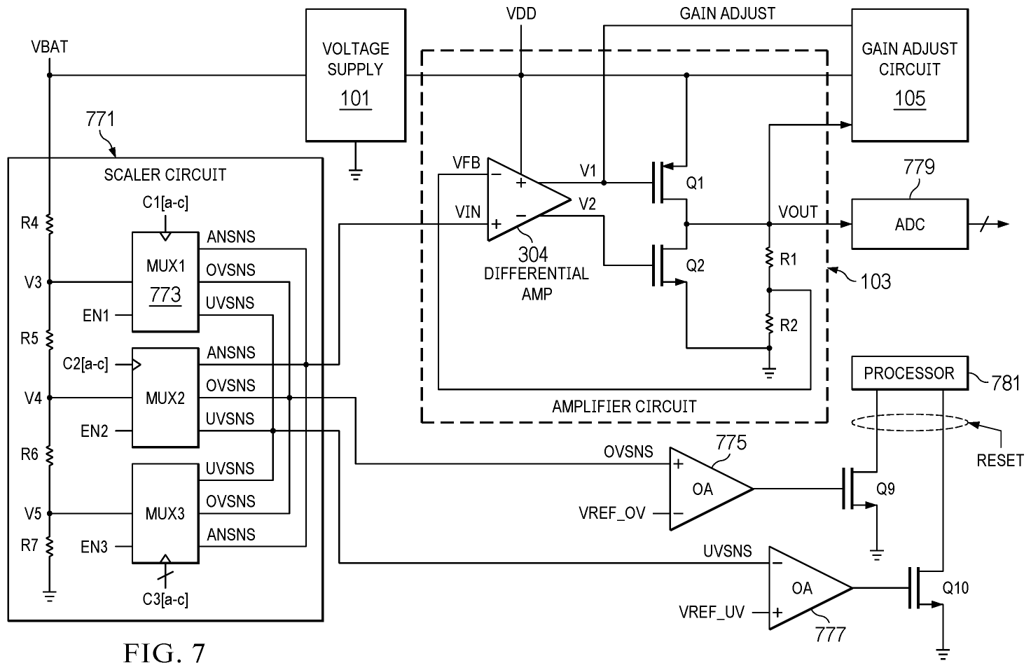

FIG. 7 illustrates a schematic diagram of a power system configured with amplifier overdrive protection, in an example. As shown, the system includes voltage supply 101, amplifier circuit 103, and gain adjust circuit 105, each of which can be implemented as described above with reference to FIGS. 1-3B, and that relevant description is equally applicable here. The system further includes a scaler circuit 771, operational amplifiers (OA) 775 and 777 (for sensing over-voltage and under-voltage conditions), analog-to-digital converter (ADC) 779, processor 781, and transistors Q9 and Q10 (which are NMOS FETs in this example, but other transistor types can be used). A battery provides voltage (VBAT) to the system. The system may be, for instance, a high-voltage to low-voltage tunable buffer and monitor system, such as might be useful in a vehicle, and in which the gain adjust circuit 105 operates to limit amplifier output current when in drop out. Any number of other applications and systems may similarly benefit from use of the techniques described herein.

The scalar circuit 771 is configured to receive and scale down battery voltage VBAT to a voltage level suitable for use by the monitoring circuit. As shown, the scalar circuit 771 includes a resistive ladder (R4 through R7) and 1-to-3 multiplex switches (MUX1 through MUX3) 773. Resistors R4 through R7 provide a high impedance resistive divider, which generates a number of smaller voltages (V3, V4, and V5) that can be used by the system. In an example, VBAT is in the range of 10 volts to 100 volts (e.g., 12 volts, 24 volts, 48 volts, or 96 volts), and the resistors R4-R7 are each in the megaohm region such that their total serial resistance is greater than 10 megaohms (e.g., 20 megaohms). So, if VBAT is 12 volts, and each of resistors R4-R7 is 5 megaohms, then: V3=0.75 (VBAT)=9 volts; V4=0.5 (VBAT)=6 volts; and V5=0.25 (VBAT) =3 volts. Each of these voltages can be provided by a corresponding MUX 773 to one off three nodes, and independently of the other two voltages, in this particular example. The three nodes include an analog sense node (ANSNS), an over-voltage sense node (OVSNS), and an under-voltage sense node (UVSNS).

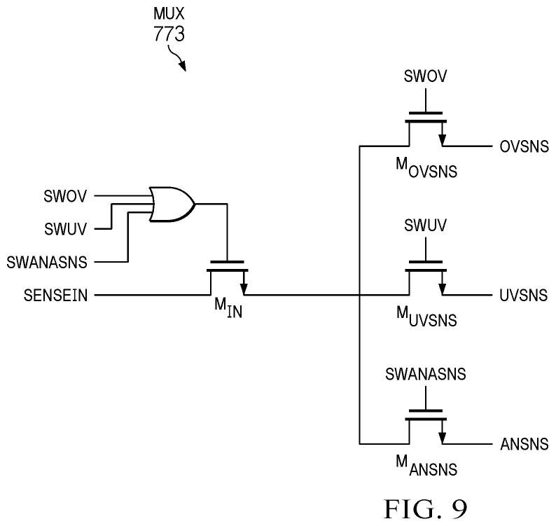

Each of MUX1, MUX2, and MUX3 can be enabled independently of the other two muxes 773, via a corresponding enable input (EN1, EN2, and EN3). Also, each of MUX1, MUX2, and MUX3 receives a 3-bit control input (C1[a-c], C2[a-c], and C3[a-c]), which can be used to select a desired one of the three output nodes. FIG. 9 shows an example schematic of such a MUX 773. As shown, MUX 773 includes a 3-input OR-gate and switches M_{IN}, M_{OVSNS}, M_{UVSNS}, and M_{ANSNS}. In this example, all the switches are implemented with FETs, although any suitable switching technology can be used. The 3-bit control input includes: SWOV, SWUV, and SWANASNS.

Each of the 3 control bits are applied to a respective input of the OR-gate. Thus, if any one bit is HIGH, then switch Mix turns on, so as to allow passage of the corresponding input voltage (V3, V4, or V5). Each of the 3 control bits are also applied to a respective control terminal (gate) of switches M_{OVSNS}, M_{UVSNS}, and M_{ANSNS}. Thus, if any one bit is HIGH, then the corresponding switch Movsxs, M_{UVSNS}, or M_{ANSNS} turns on, so as to allow passage of the corresponding input voltage (V3, V4, or V5) to the corresponding output of MUX 773 (ANSNS node, OVSNS node, or UVSNS node).

The ANSNS node is coupled to the input of the amplifier circuit 103, which in turn allows the voltage on that node to be monitored for an overdrive condition as variously described herein. As further shown in this example, the amplifier output voltage VOUT is provided to ADC 779 for conversion to the digital domain, so as to allow for further analysis and/or monitoring of the analog signals on the ANSNS node. Remedial action can be taken if a fault is detected (e.g., shut down power supply, engage redundant system, signal maintenance required, etc).

The OVSNS node is coupled to the non-inverting input of amplifier 775. The inverting input of amplifier 775 is coupled to a reference voltage VREF_OV, which allows for monitoring of an over-voltage condition on the OVSNS node. If an over-voltage condition is detected, then amplifier 775 generates a HIGH signal at its output which in turn switches on Q9 to cause a reset signal to be applied to processor 781. Responsive to that reset signal, processor 781 can initiate remedial action. Processor 781 can be any suitable processor, such as a microcontroller configured and programmed for a given application.

The UVSNS node is coupled to the inverting input of amplifier 777. The non-inverting input of amplifier 777 is coupled to a reference voltage VREF_UV, which allows for monitoring of an under-voltage condition on the UVSNS node. If an under-voltage condition is detected, then amplifier 777 generates a HIGH signal at its output which in turn switches on Q10 to cause a reset signal to be applied to processor 781. Responsive to that reset signal, processor 781 can initiate remedial action.

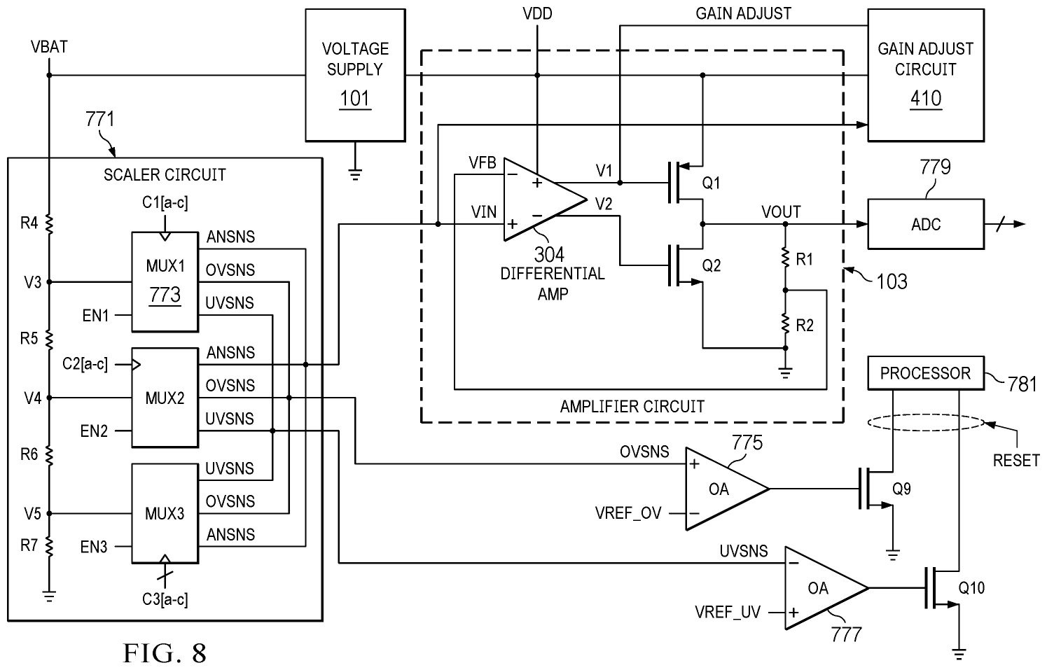

FIG. 8 illustrates a schematic diagram of a power system configured with amplifier overdrive protection, in another example. As shown, the system of FIG. 8 is similar to the system of FIG. 7, except that it includes gain adjust circuit 410 instead of gain adjust circuit 105. The above relevant description with reference to FIG. 7 for the like components is equally applicable here. Unlike gain adjust circuit 105 which senses VOUT, gain adjust circuit 410 senses VIN but still does not load the input of amplifier circuit 103, because of the very high input impedance of the gain adjust circuit 410. The above relevant description with reference to FIG. 4 is equally applicable here.

### FURTHER EXAMPLES

Example 1 is a circuit including: a power supply terminal for receiving a power supply voltage of an amplifier; an input terminal for receiving an output voltage of the amplifier; an output terminal; and a gain adjust circuit. The gain adjust circuit is configured to adjust gain of the amplifier, responsive to a difference between the amplifier output voltage and the amplifier power supply voltage exceeding a threshold voltage, by providing a gain adjust signal at the output terminal.

Example 2 includes the circuit of Example 1, wherein the gain adjust circuit includes: a comparator circuit configured to compare the amplifier output voltage and the amplifier power supply voltage, and to generate a control signal indicative of the difference exceeding the threshold voltage; and a clamp circuit configured to adjust the gain of the amplifier, responsive to the control signal.

Example 3 includes the circuit of Example 2, wherein the comparator circuit includes a hysteretic comparator circuit.

Example 4 includes the circuit of Example 2 or 3, wherein gain adjust signal includes a clamp voltage, and the clamp circuit adjusts the gain of the amplifier by clamping a drive voltage of the amplifier to the clamp voltage.

Example 5 includes the circuit of Example 4, wherein the threshold voltage is a first threshold voltage, and the clamp voltage is the power supply voltage less a second threshold voltage, such as a transistor threshold voltage (such as VSG of a FET) or a PN junction threshold (such as a forward bias voltage drop of a diode).

Example 6 includes the circuit of any one of Examples 2 through 5, wherein the clamp circuit includes: a switch coupled between the power supply terminal and a drive voltage terminal of the amplifier, the switch being controlled by the control signal; and a diode or diode-connected transistor coupled in series with the switch between the power supply terminal and the drive voltage terminal of the amplifier.

Example 7 includes the circuit of any one of Examples 1 through 6, wherein the threshold voltage is a first threshold voltage, and wherein: the gain adjust circuit is configured to decrease the gain of the amplifier from a first gain to a second gain, responsive to the difference between the amplifier output voltage and the amplifier power supply voltage exceeding the first threshold voltage, by asserting the gain adjust signal at the output terminal; and the gain adjust circuit is configured to restore the gain of the amplifier to the first gain, responsive to the difference between the amplifier output voltage and the amplifier power supply voltage no longer exceeding a second threshold voltage, by de-asserting the gain adjust signal at the output terminal, the second threshold voltage lower than the first threshold voltage so as to provide hysteresis.

Example 8 includes the circuit of any one of Examples 1 through 7, wherein: the gain adjust circuit is configured to adjust the gain of the amplifier from a first gain to a second gain, responsive to the difference between the amplifier output voltage and the amplifier power supply voltage exceeding the threshold voltage; and the gain adjust circuit is configured to restore the gain of the amplifier to the first gain, responsive to the difference between the amplifier output voltage and the amplifier power supply voltage no longer exceeding the threshold voltage.

Example 9 includes the circuit of any one of Examples 1 through 8, wherein the threshold voltage is correlated to a dropout voltage specification of the amplifier.

Example 10 is a power system that includes: the circuit of any one of Examples 1 through 9; the amplifier; and a power supply to provide the power supply voltage.

Example 11 includes the system of Example 10, wherein the amplifier includes first and second amplifier inputs, the first amplifier input to receive an input voltage, and the second amplifier input to receive a feedback voltage representative of the amplifier output voltage, and the gain adjust circuit does not load the first amplifier input, in operation.

Example 12 includes the system of Example 11, and further includes: a battery from which the input voltage is derived.

Example 13 includes the system of any one of Examples 10 through 12, and further includes: an analog-to-digital converter (ADC) configured to receive the amplifier output voltage and generate a digital signal therefrom.

Example 14 includes the system of any one of Examples 10 through 13, and further includes one or both of: an overvoltage monitoring circuit; or a undervoltage monitoring circuit.

Example 15 includes the system of any one of Examples 10 through 14, and further includes: a processor configured to assess one or more signals generated by the power system.

Example 16 is a circuit including: a power supply terminal for receiving a power supply voltage of an amplifier; an input terminal for receiving an output voltage of the amplifier; an output terminal; a comparator circuit; and a clam circuit. The comparator circuit includes first and second comparator inputs and a comparator output, the first comparator input coupled to the power supply terminal, and the second comparator input coupled to the input terminal. The clamp circuit includes first and second clamp inputs and a clamp output, the first clamp input coupled to the power supply terminal, the second clamp input coupled to the comparator output, and the clamp output coupled to the output terminal.

Example 17 includes the circuit of Example 16, wherein, responsive to a voltage difference between the first and second comparator inputs exceeding a threshold, a signal at the comparator output transitions from a first state to a second state, thereby causing the clamp circuit to engage.

Example 18 includes the circuit of Example 16 or 17, wherein: the comparator circuit is configured to determine a voltage difference between a first voltage at the first comparator input and a second voltage at the second comparator input, and to provide a control signal at the comparator output that is indicative of the voltage difference exceeding a threshold voltage; and the clamp circuit is configured to adjust gain of the amplifier, responsive to the control signal.

Example 19 includes the circuit of any one of Examples 16 through 18, wherein the comparator circuit comprises a hysteretic comparator circuit.

Example 20 includes the circuit of any one of Examples 16 through 19, wherein the clamp circuit is configured to clamp a drive voltage of the amplifier to a clamp voltage.

Example 21 includes the circuit of Example 20, wherein the clamp voltage is the power supply voltage less a threshold voltage, such as a transistor threshold voltage (such as VSG of a FET) or a PN junction threshold (such as a forward bias voltage drop of a diode).

Example 22 includes the circuit of any one of Examples 16 through 21, wherein the clamp circuit includes: a switch coupled between the power supply terminal and a drive voltage terminal of the amplifier, the switch being controlled by a control signal at the comparator output; and a diode or diode-connected transistor coupled in series with switch between the power supply terminal and the drive voltage terminal of the amplifier.

Example 23 includes the circuit of any one of Examples 16 through 22, wherein the comparator circuit comprises: a first current source; a second current source coupled between the comparator output and a ground terminal; a first transistor having first and second current terminals and a control terminal, the first current terminal of the first transistor coupled to the power supply terminal, and the second current terminal of the first transistor coupled to the control terminal of the first transistor, and the second current terminal of the first transistor also coupled to a ground terminal via the first current source; a resistor having a first and second terminals, the first terminal of the resistor coupled to the second current terminal of the first transistor, and the second terminal of the resistor coupled to the first current source; and a second transistor having first and second current terminals and a control terminal, the first current terminal of the second transistor coupled to the input terminal, the second current terminal of the second transistor coupled to the comparator output, and the control terminal of the second transistor coupled the second terminal of the resistor.

Example 24 includes the circuit of Example 23, wherein the comparator circuit includes: a third current source; and a third transistor having first and second current terminals and a control terminal, the first current terminal of the third transistor coupled to the power supply terminal via the third current source, the second current terminal of the third transistor coupled to the ground terminal, and the control terminal of the third transistor coupled to the comparator output.

Example 25 includes the circuit of Example 24, wherein the comparator circuit includes: a fourth transistor having first and second current terminals and a control terminal, the first current terminal of the fourth transistor coupled to the input terminal, and the control terminal of the fourth transistor coupled to the control terminal of the second transistor; and a fifth transistor having first and second current terminals and a control terminal, the first current terminal of the fifth transistor coupled to the second current terminal of the fourth transistor, the second current terminal of the fifth transistor coupled to the comparator output, and the control terminal of the fifth transistor coupled to the first current terminal of the third transistor.

Example 26 is a power system that includes: the circuit of any one of Examples 16 through 25; the amplifier; and a power supply to provide the power supply voltage.

Example 27 includes the system of Example 26, wherein the amplifier includes first and second amplifier inputs, the first amplifier input to receive an input voltage, and the second amplifier input to receive a feedback voltage representative of the amplifier output voltage, and the clamp circuit does not load the first amplifier input, in operation.

Example 28 includes the system of Example 27, and further includes: a battery from which the input voltage is derived.

Example 29 includes the system of any one of Examples 26 through 28, and further includes: an analog-to-digital converter (ADC) configured to receive the amplifier output voltage and generate a digital signal therefrom.

Example 30 includes the system of any one of Examples 26 through 29, and further includes one or both of: an overvoltage monitoring circuit; or a undervoltage monitoring circuit.

Example 31 includes the system of any one of Examples 26 through 30, and further includes: a processor configured to assess one or more signals generated by the power system.

Example 32 is a circuit that includes: a power supply terminal for receiving a power supply voltage of an amplifier; an input terminal for receiving an input voltage of the amplifier; an output terminal; and a gain adjust circuit. The gain adjust circuit is configured to adjust gain of the amplifier, responsive to the amplifier input voltage exceeding a reference voltage, by providing a gain adjust signal at the output terminal, the reference voltage being the power supply voltage divided by a gain of the amplifier.

Example 33 includes the circuit of Example 32, wherein the gain adjust circuit includes: a comparator circuit configured to compare the amplifier input voltage and the reference voltage, and to generate a control signal indicative of the amplifier input voltage exceeding the reference voltage; and a clamp circuit configured to adjust the gain of the amplifier, responsive to the control signal.

Example 34 includes the circuit of Example 33, wherein gain adjust signal comprises a clamp voltage, and the clamp circuit adjusts the gain of the amplifier by clamping a drive voltage of the amplifier to the clamp voltage.

Example 35 includes the circuit of Example 34, wherein the clamp voltage is the power supply voltage less a transistor threshold voltage, or a PN junction threshold (such as a forward bias voltage drop of a diode).

Example 36 includes the circuit of any one of Examples 33 through 35, wherein the clamp circuit comprises: a switch coupled between the power supply terminal and a drive voltage terminal of the amplifier, the switch being controlled by the control signal; and a diode or diode-connected transistor coupled in series with the switch between the power supply terminal and the drive voltage terminal of the amplifier.

Example 37 includes the circuit of any one of Examples 33 through 36, wherein: the gain adjust circuit is configured to adjust the gain of the amplifier from a first gain to a second gain, responsive to the amplifier input voltage exceeding the reference voltage; and the gain adjust circuit is configured to restore the gain of the amplifier to the first gain, responsive to the amplifier input voltage no longer exceeding the reference voltage.

Example 38 is a power system that includes: the circuit of any one of Examples 33 through 37; the amplifier; and a power supply to provide the power supply voltage.

Example 39 includes the system of Example 38, wherein the amplifier includes first and second amplifier inputs, the first amplifier input to receive an input voltage, and the second amplifier input to receive a feedback voltage representative of an output voltage of the amplifier, and the gain adjust circuit does not load the first amplifier input, in operation.

Example 40 includes the system of Example 39, and further includes: an analog-to-digital converter (ADC) configured to receive the amplifier output voltage and generate a digital signal therefrom.

Example 41 includes the system of any one of Examples 38 through 40, and further includes: a battery from which the amplifier input voltage is derived.

Example 42 includes the system of any one of Examples 38 through 41, and further includes one or both of: an overvoltage monitoring circuit; or a undervoltage monitoring circuit.

Example 43 includes the system of any one of Examples 38 through 42, and further includes: a processor configured to assess one or more signals generated by the power system.

Example 44 is method for providing overdrive protection of an amplifier. The method includes determining a difference of an amplifier output voltage and an amplifier power supply voltage. Responsive to the difference exceeding a threshold, the method includes limiting drive capability of the amplifier thus limiting maximum current at an output of the amplifier. Responsive to the difference not exceeding a threshold, the method includes restoring the drive capability of the amplifier.

Example 45 is a method for providing overdrive protection of an amplifier. The method includes comparing an amplifier input voltage to a reference voltage, the reference voltage equal to an amplifier power supply voltage divided by a gain of the amplifier. Responsive to the amplifier input voltage being greater than the reference voltage, the method includes limiting drive capability of the amplifier thus limiting maximum current at an output of the amplifier. Responsive to the amplifier input voltage not being greater than the reference voltage, the method includes restoring the drive capability of the amplifier.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, such as by an end user and/or a third party.

While the use of particular transistors is described herein, other transistors (or equivalent devices) may be used instead. For example, a p-channel field effect transistor (PFET) may be used in place of an n-channel field effect transistor (NFET) with little or no changes to the circuit. Furthermore, other types of transistors may be used (such as bipolar junction transistors (BJTs)). Furthermore, the devices may be implemented in/over a silicon substrate (Si), a silicon carbide substrate (SiC), a gallium nitride substrate (GaN) or a gallium arsenide substrate (GaAs), to name a few examples.

References herein to a field effect transistor (FET) being “ON” means that the conduction channel of the FET is present and drain current may flow through the FET. References herein to a FET being “OFF” means that the conduction channel is not present and drain current does not flow through the FET. A FET that is OFF, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. In another example, a resistor or capacitor shown and described herein as a single component may instead be multiple resistors or capacitors, respectively, coupled in series between the same two nodes as the single resistor or capacitor.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter.

Modifications are possible in the described embodiments, and other embodiments are possible, within the scope of the claims.

What is claimed is:

1. A circuit comprising:
a power supply terminal for receiving a power supply voltage of an amplifier;
an input terminal for receiving an output voltage of the amplifier;
an output terminal; and
a gain adjust circuit configured to adjust gain of the amplifier, responsive to a difference between the amplifier output voltage and the amplifier power supply voltage exceeding a threshold voltage, by providing a gain adjust signal at the output terminal.

2. The circuit of claim 1, wherein the gain adjust circuit includes:
a comparator circuit configured to compare the amplifier output voltage and the amplifier power supply voltage, and to generate a control signal indicative of the difference exceeding the threshold voltage; and
a clamp circuit configured to adjust the gain of the amplifier, responsive to the control signal.

3. The circuit of claim 2, wherein the comparator circuit comprises a hysteretic comparator circuit.

4. The circuit of claim 2, wherein gain adjust signal comprises a clamp voltage, and the clamp circuit adjusts the gain of the amplifier by clamping a drive voltage of the amplifier to the clamp voltage.

5. The circuit of claim 4, wherein the threshold voltage is a first threshold voltage, and the clamp voltage is the power supply voltage less a second threshold voltage.

6. The circuit of claim 2, wherein the clamp circuit comprises:
a switch coupled between the power supply terminal and a drive voltage terminal of the amplifier, the switch being controlled by the control signal; and
a diode or diode-connected transistor coupled in series with the switch between the power supply terminal and the drive voltage terminal of the amplifier.

7. The circuit of claim 1, wherein the threshold voltage is a first threshold voltage, and wherein:
the gain adjust circuit is configured to decrease the gain of the amplifier from a first gain to a second gain, responsive to the difference between the amplifier output voltage and the amplifier power supply voltage exceeding the first threshold voltage, by asserting the gain adjust signal at the output terminal; and
the gain adjust circuit is configured to restore the gain of the amplifier to the first gain, responsive to the difference between the amplifier output voltage and the amplifier power supply voltage no longer exceeding a second threshold voltage, by de-asserting the gain adjust signal at the output terminal, the second threshold voltage lower than the first threshold voltage so as to provide hysteresis.

8. The circuit of claim 1, wherein:
the gain adjust circuit is configured to adjust the gain of the amplifier from a first gain to a second gain, responsive to the difference between the amplifier output voltage and the amplifier power supply voltage exceeding the threshold voltage; and
the gain adjust circuit is configured to restore the gain of the amplifier to the first gain, responsive to the difference between the amplifier output voltage and the amplifier power supply voltage no longer exceeding the threshold voltage.

9. The circuit of claim 1, wherein the threshold voltage is correlated to a dropout voltage specification of the amplifier.

10. A power system comprising:
the circuit of claim 1;
the amplifier; and
a power supply to provide the power supply voltage.

11. A circuit comprising:
a power supply terminal for receiving a power supply voltage of an amplifier;
an input terminal for receiving an output voltage of the amplifier;
an output terminal;
a comparator circuit having first and second comparator inputs and a comparator output, the first comparator input coupled to the power supply terminal, and the second comparator input coupled to the input terminal; and
a clamp circuit having first and second clamp inputs and a clamp output, the first clamp input coupled to the power supply terminal, the second clamp input coupled to the comparator output, and the clamp output coupled to the output terminal.

12. The circuit of claim 11, wherein, responsive to a voltage difference between the first and second comparator inputs exceeding a threshold, a signal at the comparator output transitions from a first state to a second state, thereby causing the clamp circuit to engage.

13. The circuit of claim 11, wherein:
the comparator circuit is configured to determine a voltage difference between a first voltage at the first comparator input and a second voltage at the second comparator input, and to provide a control signal at the comparator output that is indicative of the voltage difference exceeding a threshold voltage; and
the clamp circuit is configured to adjust gain of the amplifier, responsive to the control signal.

14. The circuit of claim 11, wherein the comparator circuit comprises a hysteretic comparator circuit.

15. The circuit of claim 11, wherein the clamp circuit is configured to clamp a drive voltage of the amplifier to a clamp voltage.

16. The circuit of claim 15, wherein the clamp voltage is the power supply voltage less a threshold voltage.

17. The circuit of claim 11, wherein the clamp circuit comprises:
a switch coupled between the power supply terminal and a drive voltage terminal of the amplifier, the switch being controlled by a control signal at the comparator output; and
a diode or diode-connected transistor coupled in series with switch between the power supply terminal and the drive voltage terminal of the amplifier.

18. The circuit of claim 11, wherein the comparator circuit comprises:
a first current source;
a second current source coupled between the comparator output and a ground terminal;
a first transistor having first and second current terminals and a control terminal, the first current terminal of the first transistor coupled to the power supply terminal, and the second current terminal of the first transistor coupled to the control terminal of the first transistor, and the second current terminal of the first transistor also coupled to a ground terminal via the first current source;
a resistor having a first and second terminals, the first terminal of the resistor coupled to the second current terminal of the first transistor, and the second terminal of the resistor coupled to the first current source;
a second transistor having first and second current terminals and a control terminal, the first current terminal of the second transistor coupled to the input terminal, the second current terminal of the second transistor coupled to the comparator output, and the control terminal of the second transistor coupled the second terminal of the resistor;
a third current source;
a third transistor having first and second current terminals and a control terminal, the first current terminal of the third transistor coupled to the power supply terminal via the third current source, the second current terminal of the third transistor coupled to the ground terminal, and the control terminal of the third transistor coupled to the comparator output;
a fourth transistor having first and second current terminals and a control terminal, the first current terminal of the fourth transistor coupled to the input terminal, and the control terminal of the fourth transistor coupled to the control terminal of the second transistor; and
a fifth transistor having first and second current terminals and a control terminal, the first current terminal of the fifth transistor coupled to the second current terminal of the fourth transistor, the second current terminal of the fifth transistor coupled to the comparator output, and the control terminal of the fifth transistor coupled to the first current terminal of the third transistor.

19. A circuit comprising:
a power supply terminal for receiving a power supply voltage of an amplifier;
an input terminal for receiving an input voltage of the amplifier;
an output terminal; and
a gain adjust circuit configured to adjust gain of the amplifier, responsive to the amplifier input voltage exceeding a reference voltage, by providing a gain adjust signal at the output terminal, the reference voltage being the power supply voltage divided by a gain of the amplifier.

20. The circuit of claim 19, wherein the gain adjust circuit includes:
a comparator circuit configured to compare the amplifier input voltage and the reference voltage, and to generate a control signal indicative of the amplifier input voltage exceeding the reference voltage; and
a clamp circuit configured to adjust the gain of the amplifier, responsive to the control signal.
